(19) United States
(12) Patent Application Publication
(10) Pub. No.: US 2015/0070983 A1
(43) Pub. Date: Mar. 12, 2015

(54) MAGNETIC MEMORY DEVICE

(71) Applicant: Yoshinori KUMURA, Seoul (KR)

(72) Inventor: Yoshinori KUMURA, Seoul (KR)

(21) Appl. No.: 14/203,449

(22) Filed: Mar. 10, 2014

Related U.S. Application Data
(60) Provisional application No. 61/875,534, filed on Sep. 9, 2013.

(51) Int. Cl. G11C 11/16; H01L 43/02

(52) U.S. Cl. CPC G11C 11/1659; H01L 43/02
USPC 365/158; 257/421

(57) ABSTRACT

According to one embodiment, a magnetic memory device includes a bit line, a source line, a magnetoresistance effect element between the bit line and the source line, and a nonlinear element provided between the bit line and the source line and connected in series to the magnetoresistance effect element. The nonlinear element has a voltage-current characteristic in which current increases until a voltage to be applied becomes a predetermined applied voltage, when current flowing through the nonlinear element is within a range not exceeding a predetermined current, and current increases within an applied voltage range lower than the predetermined applied voltage, when current flowing through the nonlinear element is within a range exceeding the predetermined current.

### CROSS-REFERENCE TO RELATED APPLICATIONS

This application claims the benefit of U.S. Provisional Application No. 61/875,534, filed Sep. 9, 2013, the entire contents of which are incorporated herein by reference.

### FIELD

Embodiments described herein relate generally to a magnetic memory device.

### BACKGROUND

As nonvolatile memory devices, spin transfer torque (STT) magnetic memory devices have been proposed which use magnetoresistance effect elements (magnetic tunnel junction (MTJ) elements).

However, if a magnetic memory device is formed at a higher level of integration, and elements are thus made further minute, the following problems will arise. Firstly, a parasitic resistance increases and a transistor size (size in a channel width direction) decreases, as a result of which it becomes hard to ensure drive current of transistors. Secondly, since the parasitic resistance increases, an effective resistance change ratio decreases.

Therefore, it is hoped that magnetic memory devices will be provided which can obtain desired characteristics even if elements are made further minute.

### BRIEF DESCRIPTION OF THE DRAWINGS

FIG. 1 is a circuit diagram showing a basic circuitry structure of a magnetic memory device according to a first embodiment;

FIG. 2 is a view schematically showing a basic characteristic of a nonlinear element in the first embodiment;

FIG. 3 is a cross-sectional view schematically showing a basic structure of the magnetic memory device according to the first embodiment;

FIG. 4 is a cross-sectional view schematically showing a basic structure of a magnetoresistance effect element in the first embodiment;

FIG. 5 is a view for use in explaining characteristics of the magnetic memory device according to the first embodiment;

FIG. 6 is a view for use in explaining characteristics of a magnetic memory device provided as a comparative example to be compared with the first embodiment;

FIG. 7 is a circuit diagram showing a basic circuitry structure of a magnetic memory device according to a second embodiment;

FIG. 8 is a circuit diagram of another basic circuitry structure of the magnetic memory device according to the second embodiment;

FIG. 9 is a cross-sectional view schematically showing a basic structure of the magnetic memory device according to the second embodiment;

FIG. 10 is a view for use in explaining characteristics of the magnetic memory device according to the second embodiment;

FIG. 11 is a circuit diagram showing a basic circuitry structure of a magnetic memory device according to a modification of the second embodiment;

FIG. 12 is a cross-sectional view schematically showing a basic structure of the magnetic memory device according to the modification of the second embodiment;

FIG. 13 is another cross-sectional view schematically showing the basic structure of the magnetic memory device according to the modification of the second embodiment;

FIG. 14 is a view for use in explaining characteristics of the magnetic memory device according to the modification of the second embodiment;

FIG. 15 is a circuit diagram showing a basic circuitry structure of a magnetic memory device according to a third embodiment;

FIG. 16 is a view for use in explaining characteristics of the magnetic memory device according to the third embodiment;

FIG. 17 is a circuit diagram showing a basic circuitry structure of a magnetic memory device according to a modification of the third embodiment;

FIG. 18 is a view for use in explaining characteristics of the magnetic memory device according to the modification of the third embodiment;

FIG. 19 is a circuit diagram showing a basic circuitry structure of a magnetic memory device according to a fourth embodiment;

FIG. 20 is a circuit diagram showing a detailed circuitry structure of the magnetic memory device according to the fourth embodiment;

FIG. 21 is a view for use in explaining an operation of the magnetic memory device shown in FIG. 20;

FIG. 22 is a view for use in explaining characteristics of the magnetic memory device according to the fourth embodiment;

FIG. 23 is a circuit diagram showing a basic circuitry structure of a magnetic memory device according to a fifth embodiment;

FIG. 24 is a cross-sectional view schematically showing a basic structure of the magnetic memory device according to the fifth embodiment;

FIG. 25 is a view for schematically showing a basic characteristic of a nonlinear element in the fifth embodiment; and

FIG. 26 is a view for use in explaining characteristics of the magnetic memory device according to the fifth embodiment.

### DETAILED DESCRIPTION

In general, according to one embodiment, a magnetic memory device includes: a bit line; a source line; a magnetoresistance effect element provided between the bit line and the source line; and a nonlinear element provided between the bit line and the source line and connected in series to the magnetoresistance effect element, wherein the nonlinear element has a voltage-current characteristic in which current flowing through the nonlinear element increases until a voltage to be applied becomes a predetermined applied voltage, when current flowing through the nonlinear element is within a range not exceeding a predetermined current, and current flowing through the nonlinear element increases within an applied voltage range lower than the predetermined applied voltage, when current flowing through the nonlinear element is within a range exceeding the predetermined current.

Embodiments will be hereinafter described with reference to the accompanying drawings.

### First Embodiment

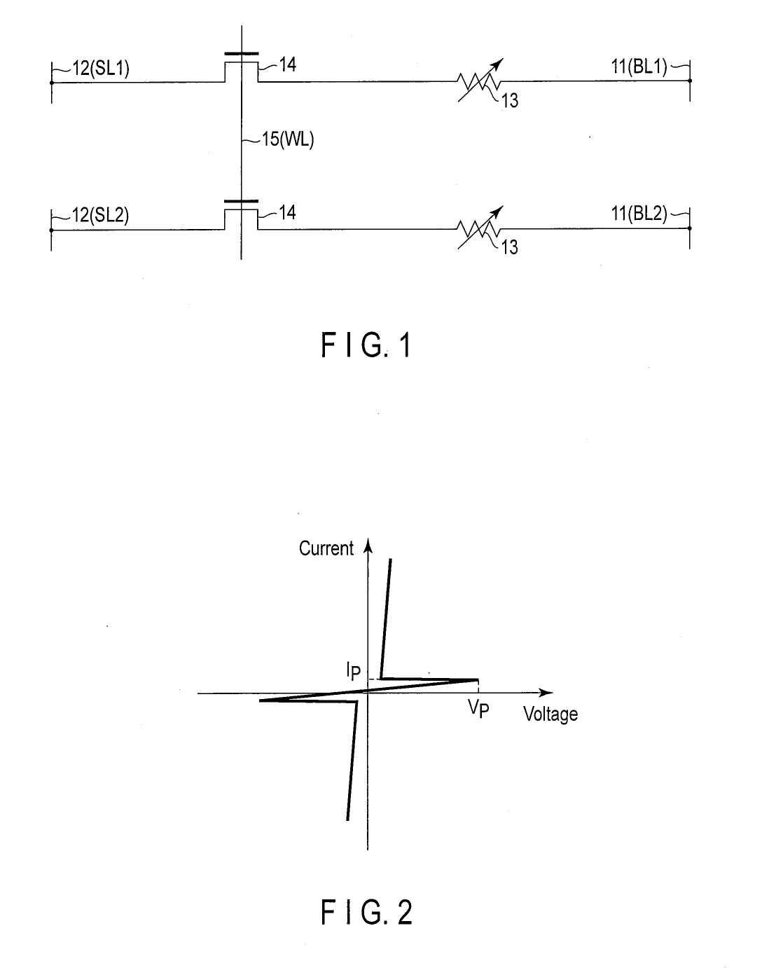

FIG. 1 is a circuit diagram showing a basic circuitry structure of a spin transfer torque (STT) magnetic memory device according to a first embodiment.

The magnetic memory device as shown in FIG. 1 comprises bit lines (BL1, BL2) 11, source lines (SL1, SL2) 12, magnetoresistance effect elements (MTJ elements) 13 provided between the bit lines 11 and the source lines 12, and triacs (nonlinear elements) 14 which are provided between the bit lines 11 and the source lines 11, connected in series to the magnetoresistance effect elements (MTJ elements) 13, and have bidirectional thyristor characteristics. To gates of the triacs 14, a word line (WL) 15 is connected. The triacs 14 are controlled (selected) by a gate voltage. Thus, unlike ordinary magnetic memories, it is not necessary to provide a switching element for selection (a transistor or the like).

FIG. 2 is a view schematically showing a basic characteristic of the triac 14 according to the first embodiment. As shown in FIG. 2, the triac 14 is a nonlinear element having a voltage-current characteristic in which current flowing through the triac 14 increases until a voltage to be applied becomes a predetermined applied voltage Vp, when the current flowing through the triac 14 is within a range not exceeding a predetermined current Ip; and current flowing through the triac 14 increases within an applied voltage range lower than the predetermined applied voltage Vp, when the current flowing through the triac 14 is within a range exceeding the predetermined current Ip. The triac 14 has a bidirectional thyristor characteristic (in positive and negative directions) as shown in FIG. 2. Due to the thyristor characteristic, the current to flow through the triac 14 steeply increases within the range exceeding the predetermined current Ip.

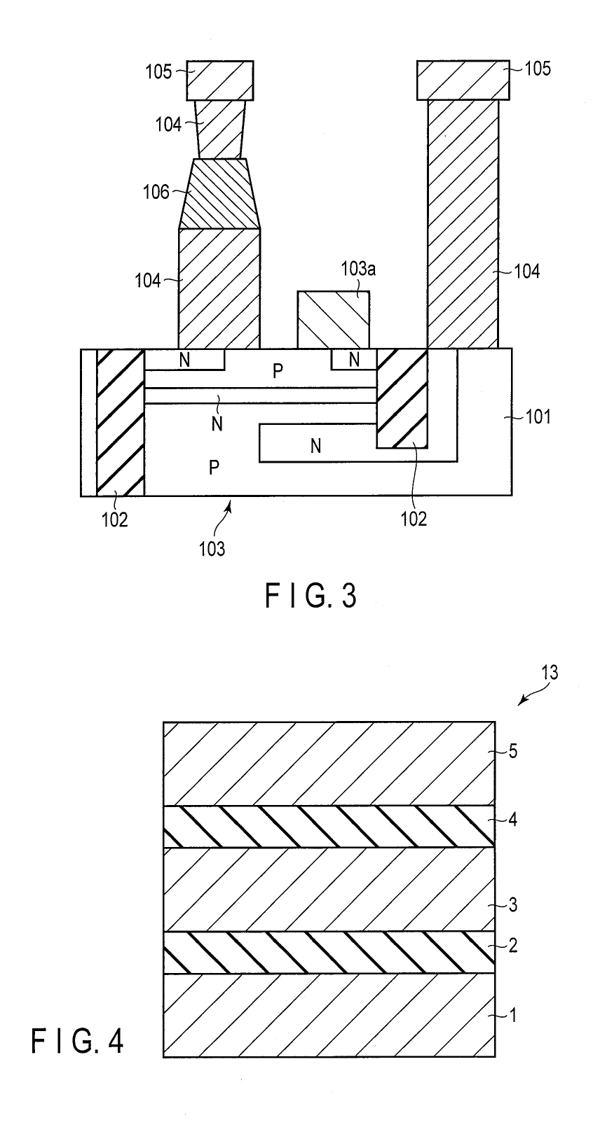

FIG. 3 is a cross-sectional view schematically showing a basic structure of the magnetic memory device according to the first embodiment. Referring to FIG. 3, in a semiconductor substrate 101, an element isolation region 102 and a triac 103 are disposed. On the semiconductor substrate 101, a gate 103a of the triac 103 is disposed. Furthermore, on the semiconductor substrate 101, plugs 104 and interconnects 105 are disposed; and an MTJ element 106 is connected to the plugs 104.

FIG. 4 is a view schematically showing a basic structure of the magnetoresistance effect element (MTJ element) 13 in the first embodiment. As shown in FIG. 4, the MTJ element 13 has a stacked structure in which a storage layer 1, a tunnel barrier layer 2 and a reference layer 3 are stacked together. In an example shown in FIG. 4, a spacer layer 4 and a shift cancelling layer 5 are further stacked.

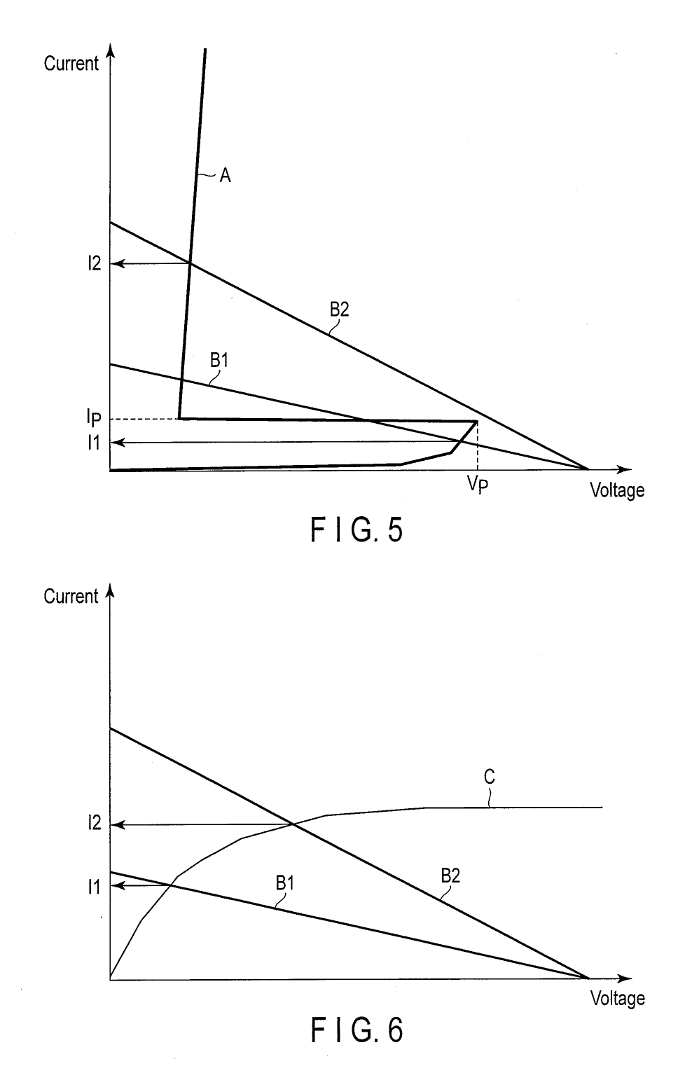

FIG. 5 is a view for use in explaining characteristics of the magnetic memory device according to the first embodiment. FIG. 6 is a view for use in explaining characteristics of a magnetic memory device disposed as a comparative example. In the comparative example, an MTJ element and a selection transistor (selection MOS transistor) are connected in series to each other.

In FIG. 6, a line C indicates a characteristic (voltage-current characteristic) of the selection transistor; a line B1 is a load line for the case where the MTJ element is in a high resistance state (antiparallel state); and a line B2 is a load line for the case where the MTJ element is in a low resistance state (parallel state). Current at an intersection of the line C and the line B1 is current I1 in the case where the MTJ element is in the high resistance state, and current at an intersection of the line C and the line B2 is current I2 in the case where the MTJ element is in the low resistance state. When elements are made further minute, a parasitic resistance increases, as a result of which an inclination of the load line B2 becomes gentler. Furthermore, transistors are made smaller in size, and thus current to flow through a selection transistor decreases (current indicated by the characteristic C decreases). As a result, the current I2 in the case where the MTJ element is in the low resistance state decreases. Inevitably, the ratio of the current I2 in the case where the MTJ element is in the low resistance state to the current I1 in the case where the MTJ element is in the high resistance state (I2/I1) decreases. That is, an effective resistance change ratio decreases. Therefore, in the comparative example, it is difficult to determine the state of the MTJ element (as 0 or 1).

On the other hand, as shown in FIG. 5, the first embodiment improves the above matter described as a problem. In FIG. 5, a line A indicates a characteristic (voltage-current characteristic) of the triac 14. A line B1 is a load line for the case where the MTJ element is in a high resistance state (antiparallel state), and a line B2 is a load line for the case where the MTJ element is in a low resistance state (parallel state). Current at an intersection of the line A and the line B1 is current I1 in the case where the MTJ element 13 is in the high resistance state, and current at an intersection of the line A and the line B2 is current I2 in the case where the MTJ element 13 is in the low resistance state.

As shown in FIG. 5, in the first embodiment, the current I1 is set in a low current region of the triac 14 (which is a current region lower than the predetermined current Ip), and the current I2 is set in a high current region of the triac 14 (which is a current region higher than the predetermined current Ip). As a result, the current I1 can be decreased, and the current I2 can be increased. Therefore, in the first embodiment, drive current of the MTJ element 13 can be increased. Also, the effective resistance change ratio (the ratio of the current I2 in the case where the MTJ element 13 is in the low resistance state to the current I1 in the case where the MTJ element is in the high resistance state (I2/I1)) can be increased.

As described above, according to the first embodiment, the drive current of the MTJ element can be increased. Also, the effective resistance change ratio can be increased. It is therefore possible to reliably determine the state of the MTJ element (as 0 or 1). Thus, according to the first embodiment, even if elements are made further minute, it is possible to provide a magnetic memory device which can obtain desired characteristics.

Also, since the triacs are provided as nonlinear elements, it is necessary to provide no selection transistor. Therefore, the circuit structure can be simplified.

### Second Embodiment

A second embodiment will be explained. It should be noted that a basic structure of the second embodiment is similar to that of the first embodiment, and explanations of the matters explained with respect to the first embodiment will thus be omitted.

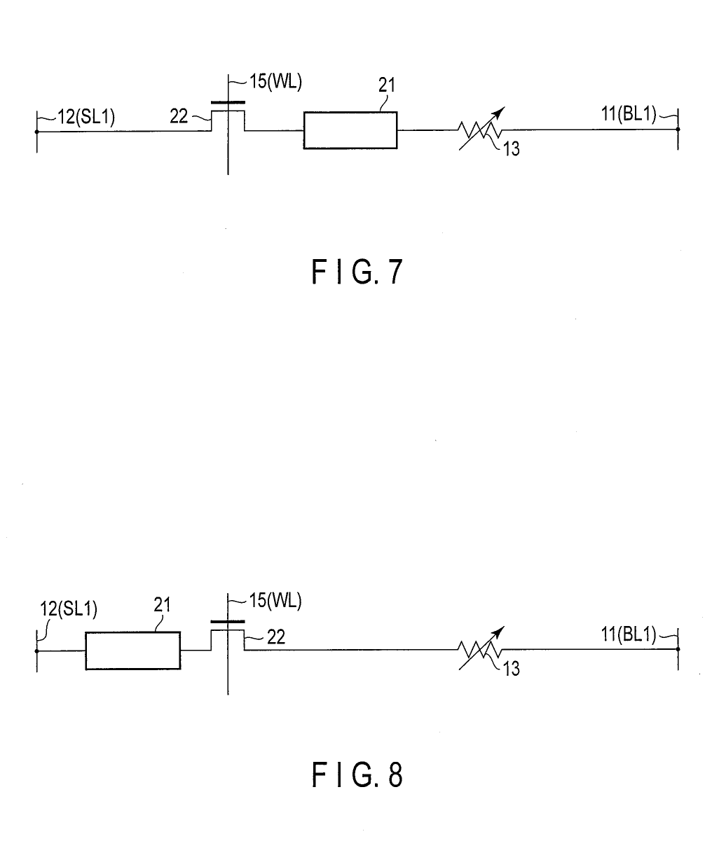

FIG. 7 is a circuit diagram showing a basic circuitry structure of an STT magnetic memory device according to the second embodiment.

A magnetic memory device as shown in FIG. 7 comprises a bit line (BL1) 11, a source line (SL1) 12, a magnetoresistance effect element (MTJ element) 13 provided between the bit line 11 and the source line 12, and a thyristor (nonlinear element) 21 between the bit line 11 and the source line 12, connected in serties to the magnetoresistance effect element (MTJ element) 13, and having a bidirectional thyristor characteristic.

Also, the magnetic memory device as shown in FIG. 7 further comprises a switching element (selection transistor) 22 between the bit line 11 and the source line 12, and connected in series to the thyristor 21 and the magnetoresistance effect element (MTJ element) 13. As the switching element 22, a MOS transistor is used. To a gate of the switching element (MOS transistor) 22, a word line (WL) 15 is connected. When the switching element 22 is selected (turned on), the MTJ element is selected.

Although in the structure as shown in FIG. 7, the thyristor 21 is provided between the switching element 22 and the bit line 11, as shown in FIG. 8, the thyristor 21 may be provided between the switching element 22 and the source line 12.

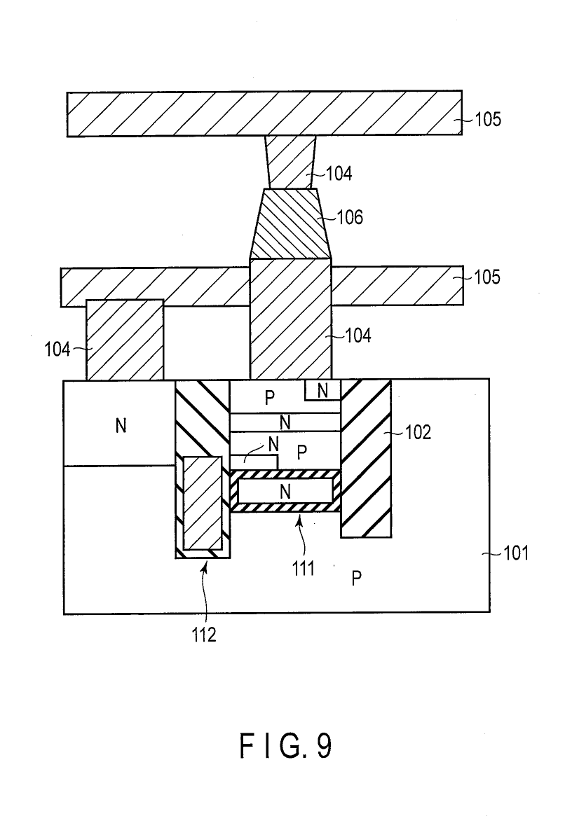

FIG. 9 is a cross-sectional view schematically showing a basic structure of the magnetic memory device according to the second embodiment. Referring to FIG. 9, in the semiconductor substrate 101, the element isolation region 102, a thyristor 111 (corresponding to the thyristor 21 as shown in FIGS. 7 and 8) and a switching element 112 (corresponding to the switching element 22 as shown in FIGS. 7 and 8) are disposed. The switching element 112 is a buried-type MOS transistor. On the semiconductor substrate 101, the plugs 104 and the interconnects 105 are disposed. To the plugs 104, the MTJ element 106 (corresponding to the MTJ element 13 as shown in FIGS. 7 and 8) is connected.

It should be noted that the thyristor 21 of the second embodiment has the same basic characteristic as explained above with reference to FIG. 2. Also, the MTJ element 13 of the second embodiment has the same basic structure as explained above with reference to FIG. 4.

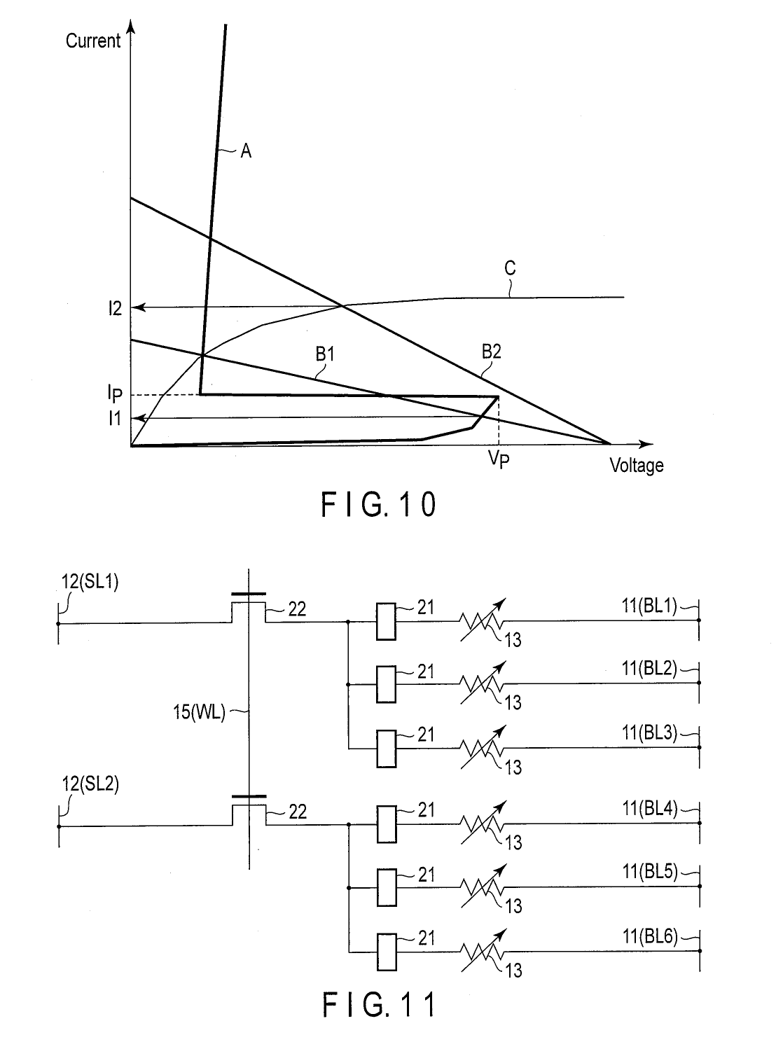

FIG. 10 is a view for use in explaining characteristics of the magnetic memory device according to the second embodiment. In FIG. 10, a line A indicates a characteristic (voltage-current characteristic) of the thyristor 21. A line B1 is a load line for the case where the MTJ element is a high resistance state (antiparallel state), and a line B2 is a load line for the case where the MTJ element is in a low resistance state (parallel state). A line C indicates a characteristic (voltage-current characteristic) of the switching element (MOS transistor) 22. Current at an intersection of the line A and the line B1 is current I1 in the case where the MTJ element 13 is in the high resistance state, and current at an intersection of the line C and the B2 is current I2 in the case where the MTJ element 13 is in the low resistance state.

As shown in FIG. 10, in the second embodiment, the current I1 is set in a low current region of the thyristor 21 (which is a current region lower than the predetermined current Ip). As a result, the current I1 can be decreased. Therefore, in the second embodiment, the effective resistance change ratio (the ratio of the current I2 in the case where the MTJ element is in the low resistance state to the current I1 in the case where the MTJ element is in the high resistance state, i.e., I2/I1) can be increased.

In such a manner, according to the second embodiment, since the effective resistance change ratio can be increased, it is possible to reliably determine the state of the MTJ element (as 0 or 1). Therefore, in the second embodiment also, even if elements are made further minute, it is possible to provide a magnetic memory device which can obtain desired characteristics.

Next, a modification of the second embodiment will be explained. It should be noted that a basic structure of the modification is similar to that of the second embodiment, explanations of the matters explained with respect to the second embodiment will thus be omitted.

FIG. 11 is a circuit diagram showing a basic circuitry structure of a magnetic memory device according to the modification of the second embodiment.

As shown in FIG. 11, in the modification, a plurality of series circuits comprising magnetoresistance effect elements (MTJ element) 13 and thyristors 21 are disposed. The series circuits are provided between bit lines 11 and source lines 12, and connected in series to switching elements (MOS transistor) 22. Each of the MTJ elements 13 is controlled independently, and also made to store information (0 or 1) independently.

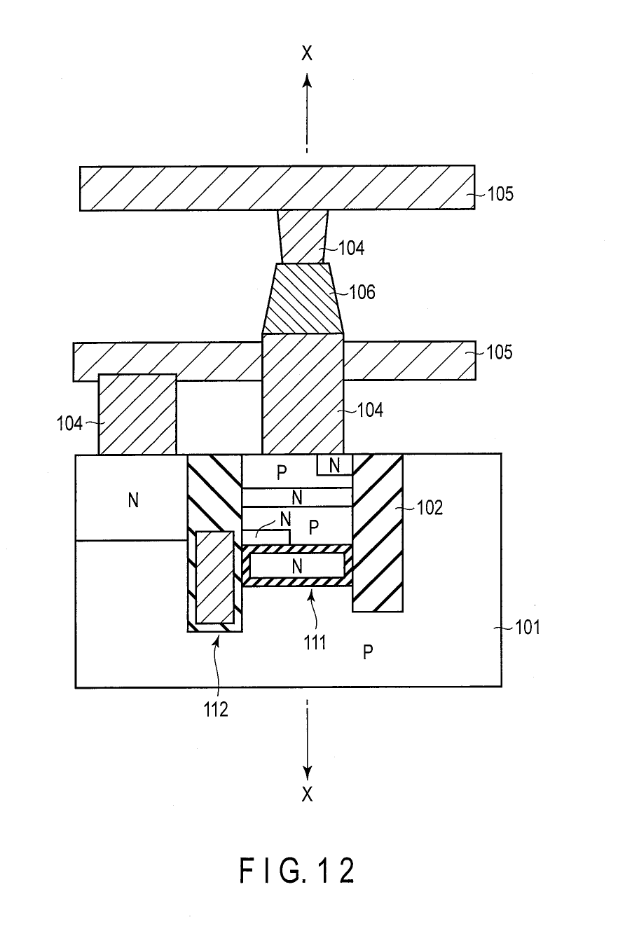

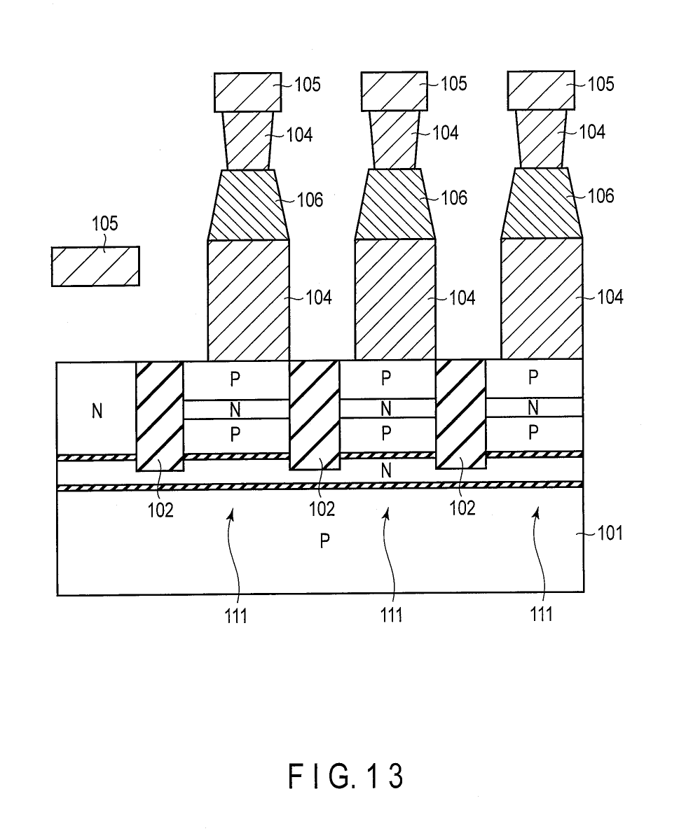

FIGS. 12 and 13 are cross-sectional views schematically showing the basic structure of the magnetic memory device according to the modification of the second embodiment. FIG. 13 is a cross-sectional view taken along line X-X in FIG. 12. Referring to FIGS. 12 and 13, in the semiconductor substrate 101, there are provided an element isolation region 102, a switching element 112 (corresponding to the switching element 22 as shown in FIG. 11) and a plurality of thyristors 111 (corresponding to the thyristor 21 as shown in FIG. 11). The switching element 112 is a buried-type MOS transistor. On the semiconductor substrate 101, the plugs 104 and the interconnects 105 are disposed, and the MTJ element 106 (corresponding to the MTJ element 13 as shown in FIG. 11) is connected to the plugs 104.

In the modification, as shown in the cross-sectional view of FIG. 13 (a cross-sectional view taken along a direction parallel to a channel width direction of the MOS transistor 112 as shown in FIG. 12), the plurality of tyristors 111 are arranged in the channel width direction of the MOS transistor 112. Thus, the channel width of the MOS transistor 112 can be increased. Therefore, on-state current of the MOS transistor 112 can be increased.

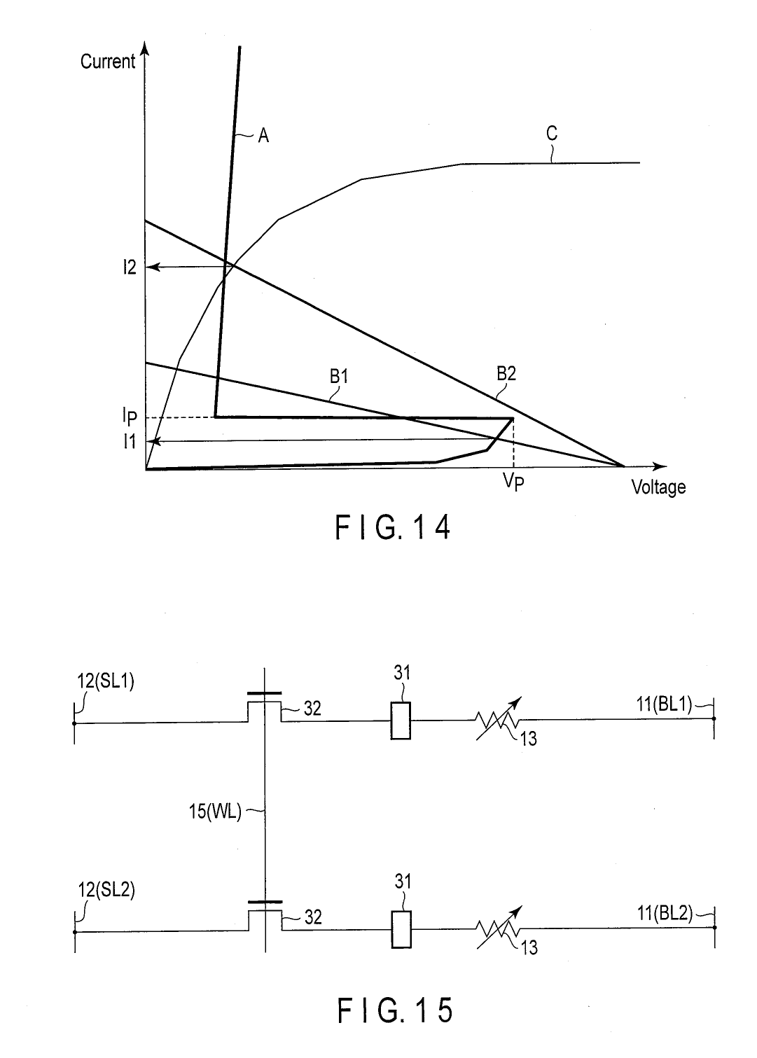

FIG. 14 is a view for use in explaining characteristics of the magnetic memory device according to the modification. In FIG. 14, a line A indicates a characteristic (voltage-current characteristic) of the thyristor 21. A line B1 is a load line for the case where the MTJ element is in a high resistance state (antiparallel state), and a line B2 is a load line for the case where the MTJ element is in a low resistance state (parallel state). A line C indicates a characteristic (voltage-current characteristic) of the switching element (MOS transistor) 22. Current at an intersection of the line A and the line B1 is current I1 in the case where the MTJ element 13 is in the high resistance state, and current at an intersection of the line C and the line B2 is current I2 in the case where the MTJ element is in the low resistance state.

In the modification, as described above, since the width of the switching element (MOS transistor) 22 in the channel width direction can be increased, on-state current of the switching element 22 can be increased. That is, in the characteristic C of the modification, the on-state current is increased, as compared with the characteristic C as shown in FIG. 10. Therefore, in the modification, the drive current of the MTJ element can be increased. Also, since the effective resistance change ratio can be increased, it is possible to more reliably determine the state of the MTJ element (as 0 or 1).

### Third Embodiment

A third embodiment will be explained. It should be noted that a basic structure of the third embodiment is similar to that of the first embodiment, and explanations of the matters explained with reference to the first embodiment will thus be omitted.

FIG. 15 is a circuit diagram showing a basic circuitry structure of an STT magnetic memory device according to the third embodiment.

The magnetic memory device as shown in FIG. 15 comprises a bit line (BL1) 11, a source line (SL1) 12, a magnetoresistance effect element (MTJ element) 13 provided between the bit line 11 and the source 12, and a GST (Ge₂Sb₂Te₅) element (nonlinear element) 31 which is provided between the bit line 11 and the source line 12, connected in series to the magnetoresistance effect element (MTJ element) 13 and having a bidirectional avalanche characteristic. The GST element 31 is a phase change element formed of chalcogenide.

Furthermore, the magnetic memory device as shown in FIG. 15 further comprises a switching element (selection transistor) 32 provided between the bit line 11 and the source line 12 and connected in series to the magnetoresistance effect element (MTJ element) 13 and the GST element 31. As the switching element 32, a MOS transistor is used. To a gate of the switching element (MOS transistor) 32, a word line (WL) 15 is connected. When the switching element 32 is selected (turned on), the MTJ element 13 is selected.

It should be noted that the GST element 31 in the third embodiment has the same basic characteristic as explained with reference to FIG. 2. Also, a basic structure of the MTJ element 13 in the third embodiment is the same as the structure explained with reference to FIG. 4.

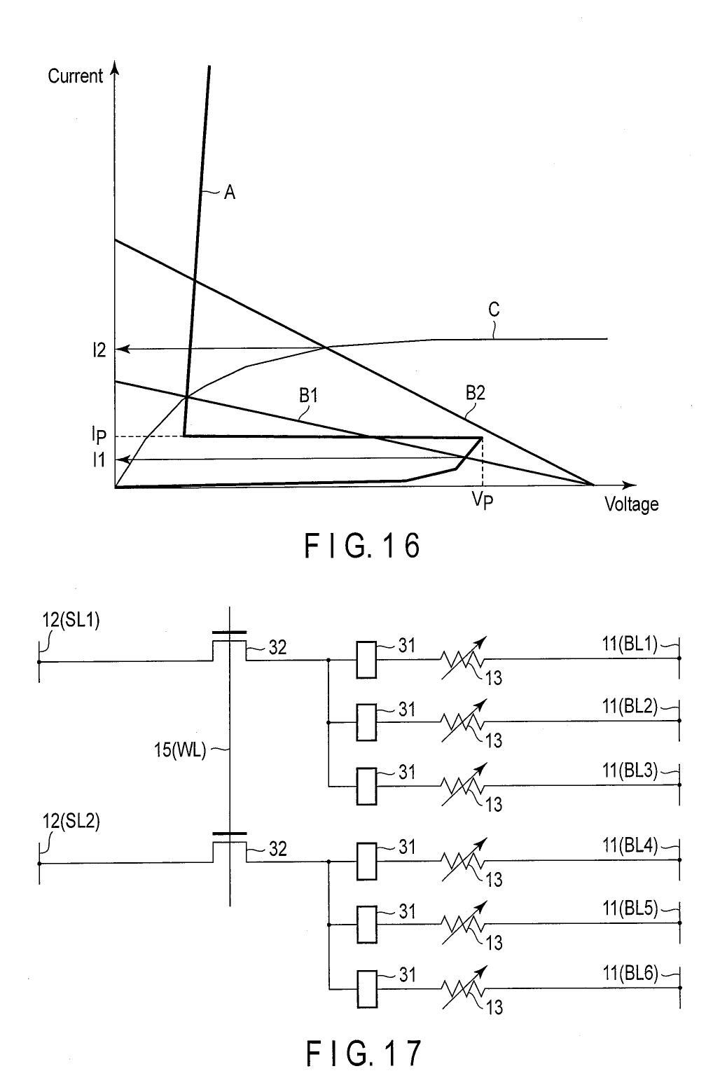

FIG. 16 is a view for use in explaining characteristics of the magnetic memory device according to the third embodiment. In FIG. 16, a line A indicates a characteristic (voltage-current characteristic) of the GST element 31. A line B1 is a load line for the case where the MTJ element is a high resistance state (antiparallel state), and a line B2 is a load line for the case where the MTJ element is in a low resistance state (parallel state). A line C indicates a characteristic (voltage-current characteristic) of the switching element (MOS transistor) 32. Current at an intersection of the line A and the line B1 is current I1 in the case where the MTJ element 13 is in the high resistance state, and current at an intersection of the line C and the line B2 is current I2 in the case where the MTJ element 13 is in the low resistance state.

As shown in FIG. 16, in the third embodiment, the current I1 is set in a low current region of the GST element 31 (which is a low current region lower than the predetermined current Ip). As a result, the current I1 can be decreased. Therefore, in third embodiment, the effective resistance change ratio (the ratio of the current I2 in the case where the MTJ element is in the low resistance state to the current I1 in the case where the MTJ element is in the high resistance state, i.e., I2/I1) can be increased.

In such a manner, in the third embodiment, since the effective resistance change ratio can be increased, it is possible to reliably determine the state of the MTJ element (as 0 or 1). Therefore, in the third embodiment, even if elements are made further minute, it is possible to provide a magnetic memory device which can obtain desired characteristics.

Next, a modification of the third embodiment will be explained. It should be noted that a basic structure of the modification is similar to those of the above embodiments, and explanations of the matters explained with respect to the embodiments will thus be omitted.

FIG. 17 is a circuit diagram showing a basic circuitry structure of a magnetic memory device according to the modification of the third embodiment.

As shown in FIG. 17, in the modification of the third embodiment, a plurality of series circuits comprising magnetoresistance effect elements (MTJ elements) 13 and GST elements 31 are disposed. The series circuits are provided between bit lines 11 and source lines 12, and connected in series to switching elements (MOS transistors) 32. Each of the MTJ elements 13 is controlled independently, and also made to store information (0 or 1) independently.

In the modification of the third embodiment, the GST elements 31 can be arranged in a channel width direction of the switching element (MOS transistor) 32 as in the modification of the second embodiment. Thus, a channel width of the MOS transistor 32 can be increased. Therefore, on-state current of the MOS transistor 32 can be increased.

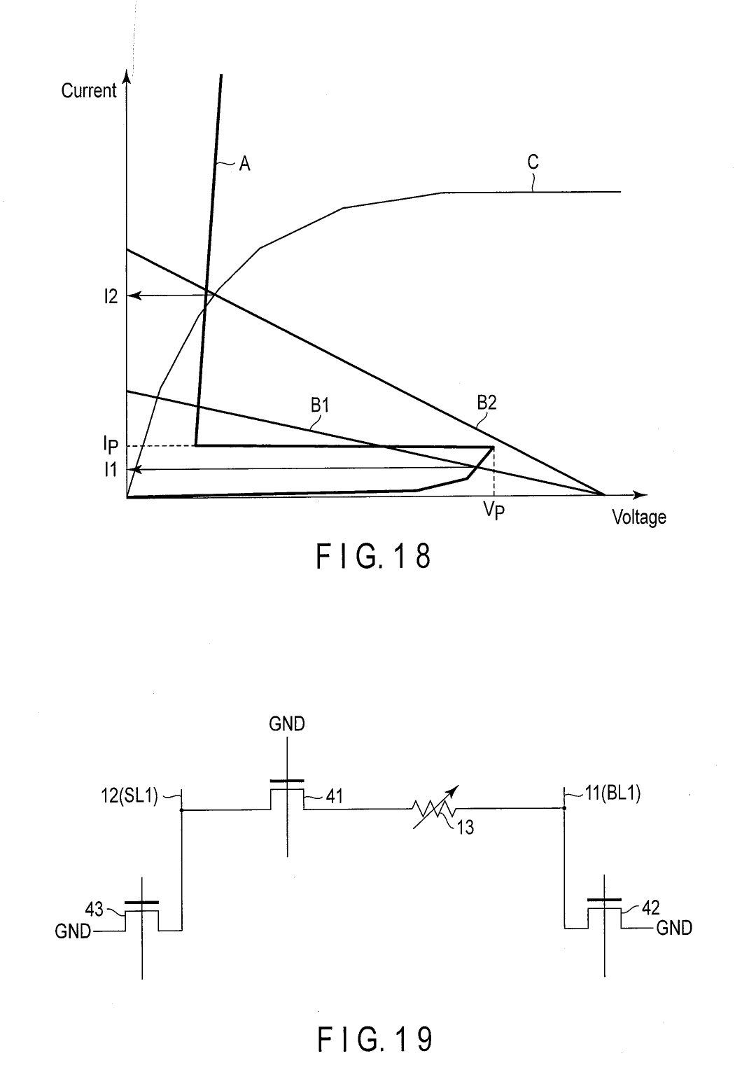

FIG. 18 is a view for use in explaining characteristics of the magnetic memory device according to the modification of the third embodiment. In FIG. 18, a line A indicates a characteristic (voltage-current characteristic) of the GST element 31. A line B1 is a load line for the case where the MTJ element is in a high resistance state (antiparallel state), and a line B2 is a load line for the case where the MTJ element is in a low resistance state (parallel state). A line C indicates a characteristic (voltage-current characteristic) of the switching element (MOS transistor) 32. Current at an intersection of the line A and the line B1 is current I1 in the case where the MTJ element 13 is in the high resistance state, and current at an intersection of the line C and the line B2 is current I2 in the case where the MTJ element 13 is in the low resistance state.

In the modification of the third embodiment, as described above, the width of the switching element (MOS transistor) 32 in the channel width direction can be increased, and thus the on-state current of the switching element 32 can be increased. That is, in the characteristic C in the modification of the third embodiment, the above on-state current is increased, as compared with the characteristic C as shown in FIG. 16. Therefore, in the modification of the third embodiment, the drive current of the MTJ element can be increased. Also, since the effective resistance change ratio can be increased, it is possible to more reliably determine the state of the MTJ element (as 0 or 1).

### Fourth Embodiment

A fourth embodiment will be explained. It should be noted that a basic structure of the fourth embodiment is similar to that of the first embodiment, and thus explanations of the matters explained with respect to the first embodiment will thus be omitted.

FIG. 19 is a circuit diagram showing a basic circuitry structure of an STT magnetic memory device according to the fourth embodiment.

The magnetic memory device as shown in FIG. 19 comprises a bit line (BL1) 11, a source line (SL1) 12, a magnetoresistance effect element (MTJ element) 13 provided between the bit line 11 and the source line 12, and a Grounded Gate MOS (GGMOS) element (nonlinear element) 41 provided between the bit line 11 and the source line 12, connected in series to the magnetoresistance effect element (MTJ element) 13, and having a bidirectional snapback characteristic. A gate of the GGMOS element 41 is connected to a ground potential.

Also, the magnetic memory device as shown in FIG. 19 further comprises a first switching element 42 configured to connect the bit line 11 to the ground potential (first potential), and a second switching element 43 configured to connect the source line 12 to the ground potential (second potential). As the switching elements 42 and 43, MOS transistors are used.

It should be noted that the GGMOS element 41 in the fourth embodiment has the same basic characteristic as explained with reference to FIG. 2. Also, a basic structure of the MTJ element 13 in the fourth embodiment is the same as that of the structure explained with reference to FIG. 4.

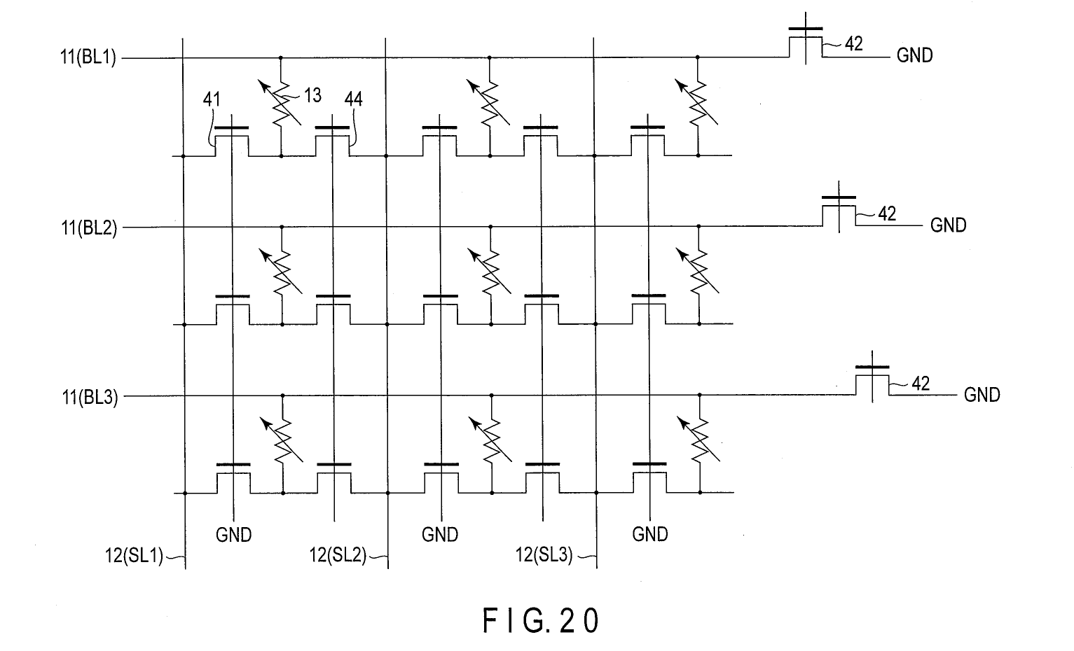

FIG. 20 is a circuit diagram showing a detailed circuitry structure of the magnetic memory device according to the fourth embodiment.

As shown in FIG. 20, circuit units comprising MTJ elements 13, GGMOS elements 41 and dummy MOS elements 44 are arrayed in a matrix.

One end of the MTJ element 13 is connected to the bit line 11, to which the switching element (MOS transistor) 42 is connected. Ordinarily, a source of the switching element (MOS transistor) 42 is grounded.

A gate of the GGMOS element 41 is grounded. A source of the GGMOS element 41 is connected to the source line 12, and a drain of the GGMOS element 41 is connected to the MTJ element 13. It should be noted that a selection transistor not shown (which corresponds to the MOS transistor 43 as shown in FIG. 19) is connected to the source line 12.

A gate of the dummy MOS element 44 is in a floating state at all times. Thus, the dummy MOS element 44 is in an off state at all times. A source of the dummy MOS element 44 is connected to the source line 12, and a drain of the dummy MOS element 44 is connected to the MTJ element 13.

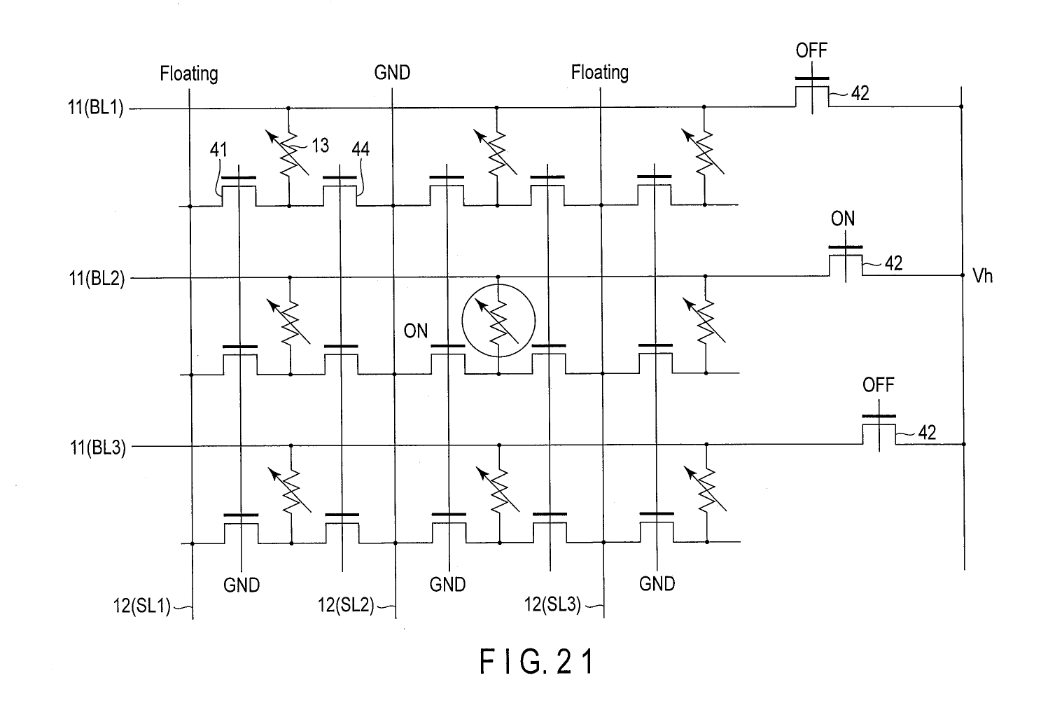

FIG. 21 is a view for use in explaining an operation of the magnetic memory device as shown in FIG. 20. It shows a case where an MTJ element 13 located at the center of FIG. 21 is selected.

In the case where the MTJ element 13 located at the center is selected, a selection transistor (MOS transistor 42) for a bit line (BL2) 11 connected to the MTJ element 13 located at the center is turned on. At this time, a predetermined voltage Vh (e.g., Vh=1V) is applied to a source of each of selection transistors (MOS transistors 42). Furthermore, a source line (SL2) for the GGMOS element 41 connected to the MTJ element 13 located at the center is grounded, and the other source lines (SL1, SL3) are made in a floating state. As a result, the GGMOS element 41 connected to the MTJ element 13 located at the center is turned on and the MTJ element 13 at the center is selected.

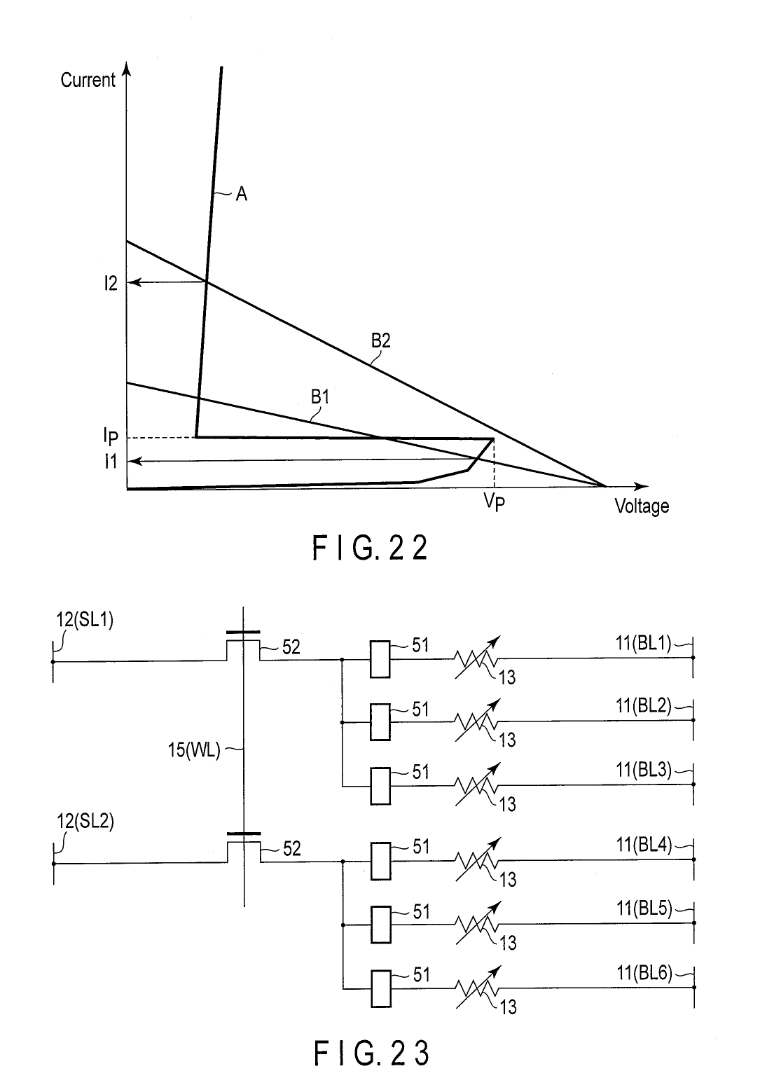

FIG. 22 is a view for use in explaining a characteristic of the magnetic memory device according to the fourth embodiment. In FIG. 22, a line A indicates a characteristic (voltage-current characteristic) of the GGMOS element 41. A line B1 is a load line for the case where the MTJ element is in a high resistance state (antiparallel state), and a line B2 is a load line for the case where the MTJ element is in a low resistance state (parallel state). Current at an intersection of the line A and the line B1 is current I1 in the case where the MTJ element 13 is in the high resistance state, and current at an intersection of the line A and the line B2 is the current I2 in the case where the MTJ element 13 is in the low resistance state.

As shown in FIG. 22, in the fourth embodiment, the current I1 is set in a low current region of the GGMOS element 41 (which is a current region lower than the predetermined current Ip), and the current I2 is set in a high current region of the GGMOS element 41 (which is a current region higher than the predetermined current Ip). As a result, the current I1 can be decreased, and the current I2 can be increased. Therefore, in the fourth embodiment, the drive current of the MTJ element 13 can be increased. Also, the effective resistance change ratio (the ratio of the current I2 in the case where the MTJ element 13 is in the low resistance state to the current I1 in the case where the MTJ element 13 is in the high resistance state, i.e., I2/I1) can be increased.

In such a manner, according to the fourth embodiment, the drive current of the MTJ element can be increased. Also, the effective resistance change ratio can be increased. Thus, it is possible to reliably determine the state of the MTJ element (as 0 or 1). Therefore, in the fourth embodiment also, even if elements are made further minute, it is possible to provide a magnetic memory device which can obtain desired characteristics.

Furthermore, since the GGMOS element is used as the nonlinear element, it is not necessary to provide a selection transistor. Therefore, the circuit structure can be simplified.

### Fifth Embodiment

A fifth embodiment will be explained. It should be noted that a basic structure of the fifth embodiment is similar to that of the first embodiment, and explanations of the matters explained with respect to the first embodiment will be omitted.

FIG. 23 is a basic circuitry structure of an STT magnetic memory device according to the fifth embodiment.

The magnetic memory device as shown in FIG. 23 comprises bit lines (BL1-BL6) 11, source lines (SL1, SL2) 12, a plurality of series circuits provided between the bit lines 11 and the source lines 12, and switching elements (MOS transistors) 52 provided between the bit lines 11 and the source lines 12 and connected in series to the series circuits. Each of the series circuits comprises a magnetoresistance effect element (MTJ element) 13 and a diode (nonlinear element) 51 having a bidirectional diode characteristic. The diode 51 is formed of insulating material such as TiO₂, HfO₂, Al₂O₃, SiN, or the like. To a gate of the switching element (MOS transistor) 52, a word line (WL) 15 is connected.

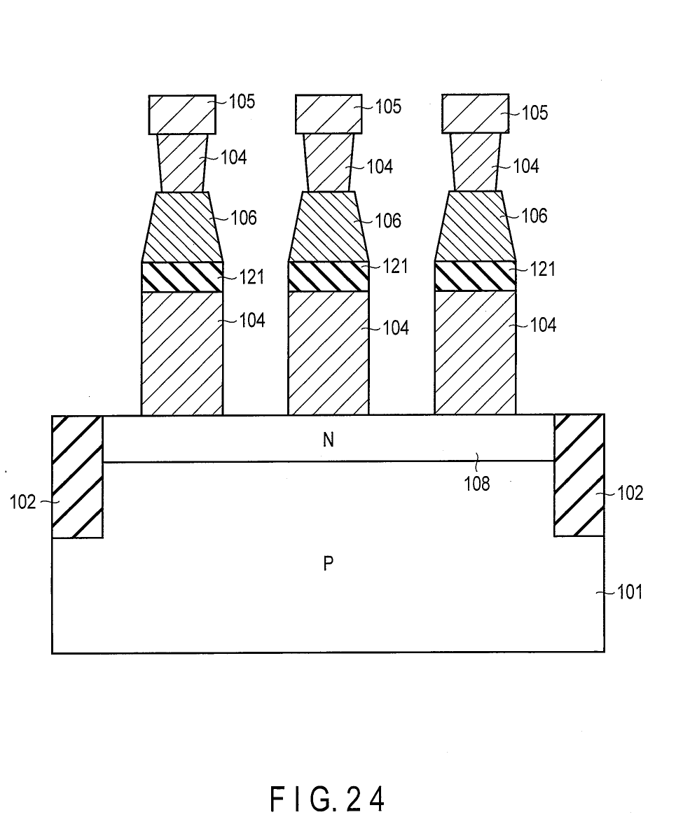

FIG. 24 is a cross-sectional view schematically showing a basic structure of a magnetic memory device according to the fifth embodiment. To be more specific, FIG. 24 is a cross-sectional view taken along a line parallel to a channel width direction of the switching element (MOS transistor) 52 shown in FIG. 23. Referring to FIG. 24, in the semiconductor substrate 101, an element isolation region 102 and a diffusion region (source region or drain region) 108 of the MOS transistor (corresponding to the switching element 52 in FIG. 23) is provided. On the semiconductor substrate 101, the plugs 104 and the interconnects 105 are disposed. Between the plugs 104, a series circuit comprising an MTJ element 106 (corresponding to the MTJ element 13 shown in FIG. 23) and a diode 121 (corresponding to the diode 51 shown in FIG. 23) is provided.

In the fifth embodiment, as shown in FIG. 24, a plurality of series circuits (comprising MTJ elements 106 and diodes 121) are arranged in the channel width direction of the MOS transistor (corresponding to the switching element 52 as shown in FIG. 23). That is, a parallel circuit unit 50 (see FIG. 23) comprising the plurality of series circuits is connected to the diffusion region (source or drain) 108 of the MOS transistor. Thus, the channel width of the MOS transistor can be increased. Therefore, on-state current of the MOS transistor can be increased.

It should be noted that in an example shown in FIG. 24, the diode 121 is provided between the MTJ element 106 and a lower one of the plugs 104; however, the position of the diode 121 can be changed as appropriate. For example, the diode 121 may be provided between the MTJ element 106 and an upper one of the plugs 104. Also, the diode 121 may be disposed under the lower plug 104 or on the upper plug 104. In addition, the GST element 31 explained with respect to the third embodiment can be disposed in the same position as the diode 121 of the fifth embodiment.

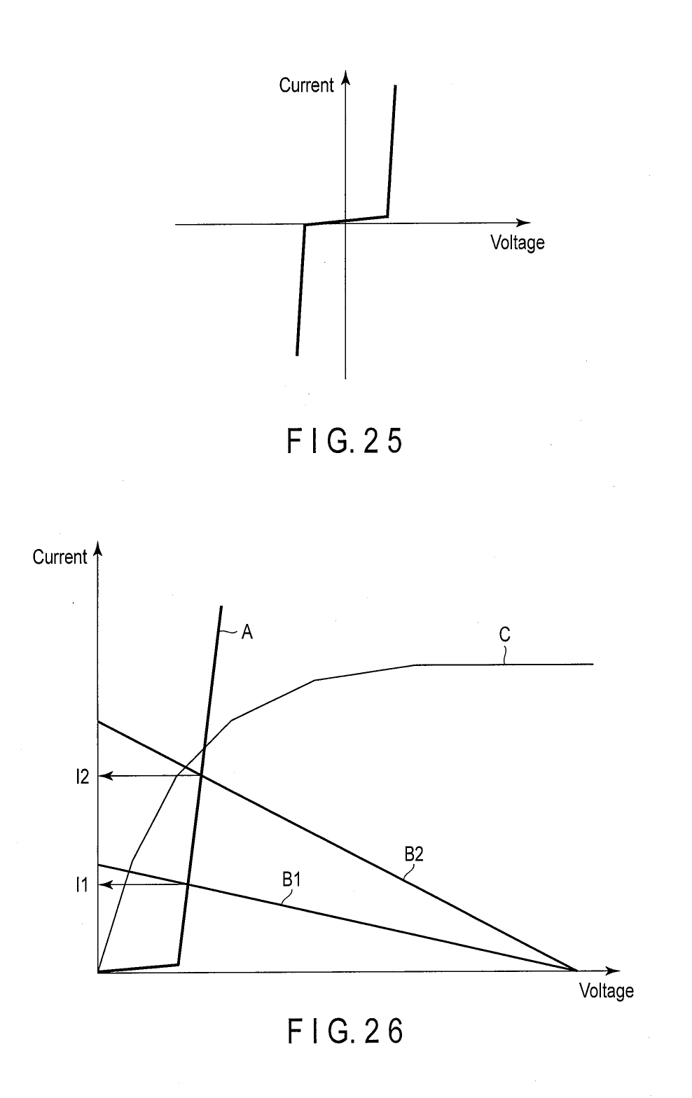

FIG. 25 is a view schematically showing a basic characteristic of the diode 51 in the fifth embodiment. As shown in FIG. 25, the diode 51 has a bidirectional diode characteristic.

It should be noted that a basic structure of the MTJ element 13 in the fifth embodiment is the same as that of the structure shown in FIG. 4 as described above.

FIG. 26 is a view for use in explaining characteristics of the magnetic memory device according to the fifth embodiment. In FIG. 25, a line A indicates a characteristic (voltage-current characteristic) of the diode 51. A line B1 is a load line for the case where the MTJ element is in a high resistance state (antiparallel state), and a line B2 is a load line for the case where the MTJ element is in a low resistance state (parallel state). A line C indicates a characteristic (voltage-current characteristic) of the switching element (MOS transistor) 52. Current at an intersection of the line A and the line B1 is current I1 in the case where the MTJ element 13 is in the high resistance state, and current at an intersection of the line A and the line B2 is current I2 in the case where the MTJ element 13 is in the low resistance state.

In the fifth embodiment, as described above, the width of the switching element (MOS transistor) 52 in the channel width direction can be increased, and thus on-state current of the switching element 52 can be increased. If the on-state current of the switching element 52 is small, the current I2 in the case where the MTJ element 13 is in the low resistance state is limited by the on-state current of the switching element 52. This causes the effective resistance change ratio to be small. In the fifth embodiment, the on-state current of the switching element 52 can be increased, and thus the current I2 in the case where the MTJ element 13 is in the low resistance state can be increased. Therefore, in the fifth embodiment, the drive current of the MTJ element 13 can be increased. Also, the effective resistance change ratio can be increased, and it is possible to reliably determine the state of the MTJ element (as 0 or 1).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory device comprising:
a bit line;
a source line;
a magnetoresistance effect element provided between the bit line and the source line; and
a nonlinear element provided between the bit line and the source line and connected in series to the magnetoresistance effect element,
wherein the nonlinear element has a voltage-current characteristic in which current flowing through the nonlinear element increases until a voltage to be applied becomes a predetermined applied voltage, when current flowing through the nonlinear element is within a range not exceeding a predetermined current, and current flowing through the nonlinear element increases within an applied voltage range lower than the predetermined applied voltage, when current flowing through the nonlinear element is within a range exceeding the predetermined current.

2. The magnetic memory device of claim 1, wherein the magnetoresistance effect element has a structure in which at least a storage layer, a tunnel barrier layer and a reference layer are stacked together.

3. The magnetic memory device of claim 1, wherein the nonlinear element is a triac.

4. The magnetic memory device of claim 3, wherein a word line is connected to a gate of the triac.

5. The magnetic memory device of claim 1, wherein the nonlinear element is a thyristor.

6. The magnetic memory device of claim 5, further comprising a switching element provided between the bit line and the source line and connected in series to the magnetoresistance effect element and the thyristor.

7. The magnetic memory device of claim 6, wherein the switching element is a MOS transistor.

8. The magnetic memory device of claim 1, wherein the nonlinear element is a GST element.

9. The magnetic memory device of claim 8, further comprising a switching element provided between the bit line and the source line and connected in series to the magnetoresistance effect element and the GST element.

10. The magnetic memory device of claim 9, wherein the switching element is a MOS transistor.

11. The magnetic memory device of claim 1, wherein the nonlinear element is a GGMOS element.

12. The magnetic memory device of claim 11, further comprising:
a first switching element configured to couple the bit line to a first potential; and
a second switching element configured to couple the source line to a second potential.

13. The magnetic memory device of claim 12, wherein the first potential and the second potential are ground potentials.

14. The magnetic memory device of claim 1, further comprising:
a second bit line;
a second magnetoresistance effect element provided between the second bit line and the source line; and
a second nonlinear element provided between the second bit line and the source line and connected in series to the second magnetoresistance effect element,
wherein an end of a first series circuit comprising the magnetoresistance effect element and the nonlinear element is connected to an end of a second series circuit comprising the second magnetoresistance effect element and the second nonlinear element.

15. A magnetic memory device comprising:
a first bit line;
a second bit line;
a source line;
a first series circuit which is provided between the first bit line and the source line, and in which a first magnetoresistance effect element and a first nonlinear element having a bidirectional diode characteristic are connected in series;
a second series circuit which is provided between the second bit line and the source line, and in which a second magnetoresistance effect element and a second nonlinear element having a bidirectional diode characteristic are connected in series; and
a switching element provided between the source line and the first and second bit lines, connected in series to the first series circuit, and connected in series to the second series circuit.

16. The magnetic memory device of claim 15, wherein each of the first and second magnetoresistance effect elements has a structure in which a storage layer, a tunnel barrier layer and a reference layer are stacked together.

17. The magnetic memory device of claim 15, wherein the switching element is a MOS transistor.

18. The magnetic memory device of claim 17, wherein a word line is connected to a gate of the MOS transistor.

19. The magnetic memory device of claim 17, wherein each of the first and second series circuits is connected to a source or a drain of the MOS transistor.
